(19) United States
(12) Patent Application Publication
(10) Pub. No.: US 2024/0012184 A1
(43) Pub. Date: Jan. 11, 2024

(54) OPTICAL FILM AND BACKLIGHT MODULE

(71) Applicant: Sunrise Optronics Co., Ltd., Taoyuan City (TW)

(72) Inventor: Wen-Feng Cheng, Taoyuan City (TW)

(73) Assignee: Sunrise Optronics Co., Ltd., Taoyuan City (TW)

(21) Appl. No.: 18/205,567

(22) Filed: Jun. 5, 2023

Related U.S. Application Data
(60) Provisional application No. 63/359,765, filed on Jul. 8, 2022.

(51) Int. Cl. G02B 5/02; G02B 5/04

(52) U.S. Cl. CPC G02B 5/0231; G02B 5/045; G02B 5/0226; H01L 33/58

(57) ABSTRACT

An optical film comprising a first surface and a second surface is provided and the first surface and the second surface face in opposite directions. The first surface is disposed with a plurality of first microstructures and a plurality of second microstructures, which are closely adjacent to each other. The first microstructures are upwardly convex quadrangular pyramid structures or triangular pyramid structures, while the second microstructures are downwardly concave quadrangular pyramid structures or triangular pyramid structures.

### BACKGROUND OF THE INVENTION

### 1. Field of the Invention

The present invention is in related to optical film and a backlight module, more particularly to the film and the backlight module applied to the field of display.

### 2. Description of the Prior Art

The backlight module is one of the main components of modern liquid crystal displays, featuring a plurality of light-emitting components to provide the light source required for the liquid crystal display. In order to make the light emitted by these components more uniform and improve the quality of the displayed images on the liquid crystal screen, a common solution is to include a diffuser plate in the direct-lit backlight module. The diffuser plate has patterns on its surface, which utilize physical phenomena such as refraction, reflection, or scattering of light to achieve a more uniform light distribution.

With the advancement of technology, in order to improve the contrast of displays, the light-emitting components of backlight modules are gradually replaced by Mini Light Emitting Diodes (Mini LEDs) instead of conventional Light Emitting Diodes (LEDs). As Mini LEDs have a smaller light-emitting area, traditional diffuser plates cannot effectively disperse the light emitted by Mini LEDs. Please refer to FIGS. 1 to 3, where FIG. 1 illustrates a conventional backlight module, FIG. 2 illustrates a brightness distribution diagram of a light source, and FIG. 3 illustrates a brightness distribution diagram of a conventional backlight module. FIG. 3 is the brightness distribution diagram at the A-A cross-sectional line position in FIG. 6. The conventional backlight module 10 includes a substrate 11, a light source 12, and a plurality of diffusion films 13, which achieve the diffusion effect through rough surfaces or coating of diffusive particles. Further comparing FIGS. 2 and 3, FIG. 2 is a brightness distribution diagram of a single light source, while FIG. 3 is a brightness distribution diagram with three diffusion films 13 covering the light source 12. From this, it can be seen that although the diffusion films 13 can achieve a diffusion effect, the effect is not ideal. The light in FIG. 3 is still concentrated between the horizontal axis 5, 4 and −4, −5, which is the position where the light source 12 is placed.

Please refer to FIGS. 4 and 5. FIG. 4 shows a backlight module with an additional prism sheet 14, and FIG. 5 shows the brightness distribution diagram of the backlight module in FIG. 4. As can be seen from FIG. 5, the light is further diffused, but the performance is still not satisfactory, as the light is still concentrated around the light source. Furthermore, traditional diffuser films 13 in the backlight module 10 would also generate higher electrostatic adhesion.

As it can be seen, how to solve aforesaid shortcoming becomes an important issue to persons who are skilled in the art.

### SUMMARY OF THE INVENTION

The first objective of the present invention is to provide an optical film and a backlight module, which address the limitations and drawbacks of the prior art.

In one aspect, an optical film comprising a first surface and a second surface is provided and the first surface and the second surface face in opposite directions. The first surface is disposed with a plurality of first microstructures and a plurality of second microstructures, which are closely adjacent to each other. The first microstructures are upwardly convex quadrangular pyramid structures or triangular pyramid structures, while the second microstructures are downwardly concave quadrangular pyramid structures or triangular pyramid structures.

In another aspect, the present invention provides a backlight module, which includes a light source array with a plurality of light sources and a plurality of stacked optical films disposed above the light source array. The optical films comprise the aforementioned first and second microstructures, which enable improved light diffusion and distribution as compared to the conventional diffuser films and prism sheets.

The present invention overcomes the limitations of traditional diffuser films in effectively diffusing light emitted from smaller light sources, such as Mini LEDs. Furthermore, the inventive optical films and backlight module exhibit reduced electrostatic adhesion compared to traditional diffuser films, thereby improving the overall performance and quality of display screens.

Other and further features, advantages, and benefits of the invention will become apparent in the following description taken in conjunction with the following drawings. It is to be understood that the foregoing general description and following detailed description are exemplary and explanatory but are not to be restrictive of the invention. The accompanying drawings are incorporated in and constitute a part of this application and, together with the description, serve to explain the principles of the invention in general terms. Like numerals refer to like parts throughout the disclosure.

### BRIEF DESCRIPTION OF THE DRAWINGS

The objects, spirits, and advantages of the preferred embodiments of the present invention will be readily understood by the accompanying drawings and detailed descriptions, wherein:

FIG. 1 illustrates a conventional backlight module.

FIG. 2 illustrates a brightness distribution diagram of a light source.

FIG. 3 illustrates a brightness distribution diagram of a conventional backlight module.

FIG. 4 illustrates a backlight module with an additional prism sheet 14.

FIG. 5 illustrates a brightness distribution diagram of the backlight module in FIG. 4.

FIG. 6 illustrates an optical simulation diagram.

FIG. 7 illustrates a schematic diagram of an optical film according to a first embodiment of the invention.

FIG. 8 illustrates a side cross-sectional view of the optical film.

FIG. 9 illustrates a schematic diagram of a microstructure.

FIGS. 10 and 11 illustrate an optical film 200 of a second embodiment.

FIGS. 12 and 13 illustrate an optical film sheet 100′ of a third embodiment.

FIGS. 14 and 15 illustrate schematic diagrams of angles θ.

FIGS. 16 and 17 illustrate a second surface 3112 of an optical film 300 of a fourth embodiment.

FIG. 18 illustrates an optical film 300′ of a fifth embodiment.

FIGS. 19 and 20 illustrate an optical film 400 of a sixth embodiment.

FIGS. 21 and 22 illustrate a disposing method of a third microstructure 430.

FIG. 23 illustrates a schematic diagram of a backlight module.

FIG. 24 illustrates a setting schematic diagram of a prism sheet.

FIG. 25 illustrates a backlight module of a first embodiment.

FIG. 26 illustrates a brightness distribution diagram of the backlight module of the first embodiment.

FIG. 27 illustrates a backlight module of a second embodiment.

FIG. 28 illustrates a brightness distribution diagram of the backlight module of the second embodiment.

FIG. 29 illustrates a backlight module of a third embodiment.

FIG. 30 illustrates a brightness distribution diagram of the backlight module of the third embodiment.

FIG. 31 illustrates a backlight module of a fourth embodiment.

FIG. 32 illustrates a brightness distribution diagram of the backlight module of the fourth embodiment.

FIG. 33 illustrates a backlight module of a fifth embodiment.

FIG. 34 illustrates a brightness distribution diagram of the backlight module of the fifth embodiment.

FIG. 35 illustrates a backlight module of a sixth embodiment.

FIG. 36 illustrates a brightness distribution diagram of the backlight module of the sixth embodiment.

FIG. 37 illustrates a backlight module of a seventh embodiment.

FIG. 38 illustrates a brightness distribution diagram of the backlight module of the seventh embodiment.

FIG. 39 illustrates a backlight module of an eighth embodiment.

FIG. 40 illustrates a brightness distribution diagram of the backlight module of the eighth embodiment.

FIG. 41 illustrates a backlight module of a ninth embodiment.

FIG. 42 illustrates a brightness distribution diagram of the backlight module of the ninth embodiment.

FIG. 43 illustrates a backlight module of a tenth embodiment.

FIG. 44 illustrates a brightness distribution diagram of the backlight module of the tenth embodiment.

FIG. 45 illustrates a backlight module of an eleventh embodiment.

FIG. 46 illustrates a brightness distribution diagram of the backlight module of the eleventh embodiment.

FIG. 47 illustrates a backlight module of a twelfth embodiment.

FIG. 48 illustrates a brightness distribution diagram of the backlight module of the twelfth embodiment.

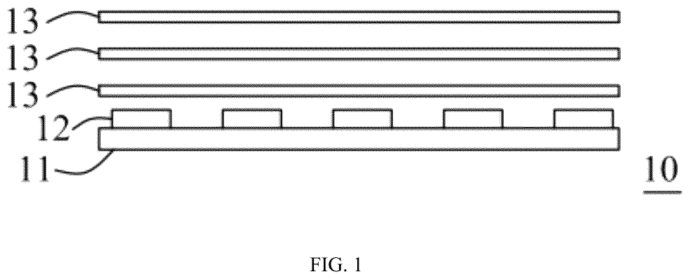

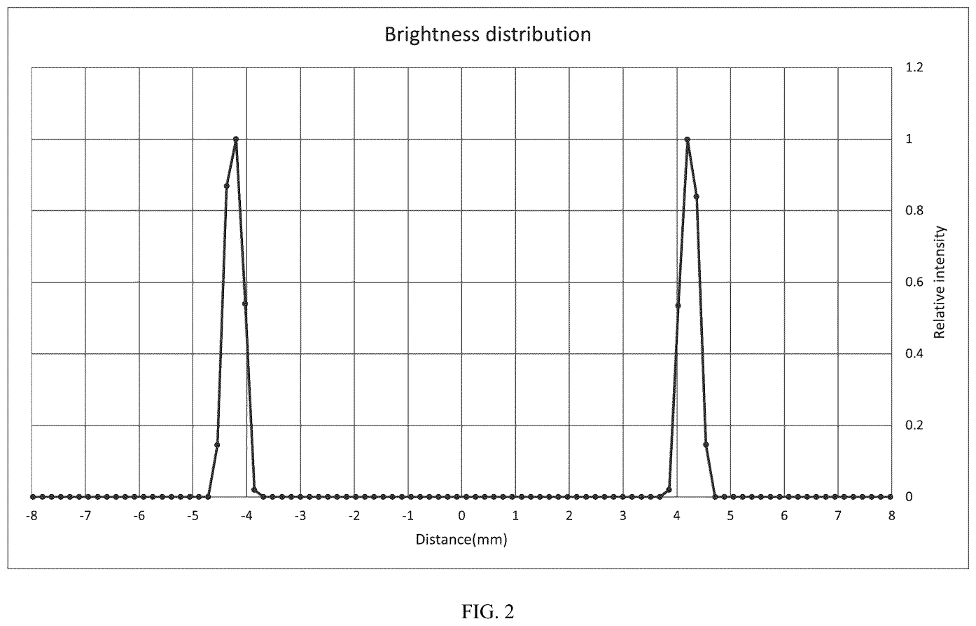

### DETAILED DESCRIPTION OF THE INVENTION

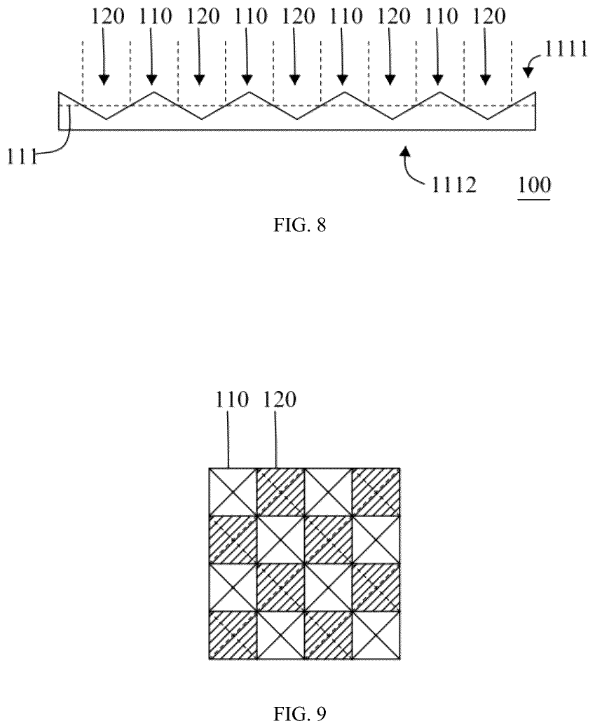

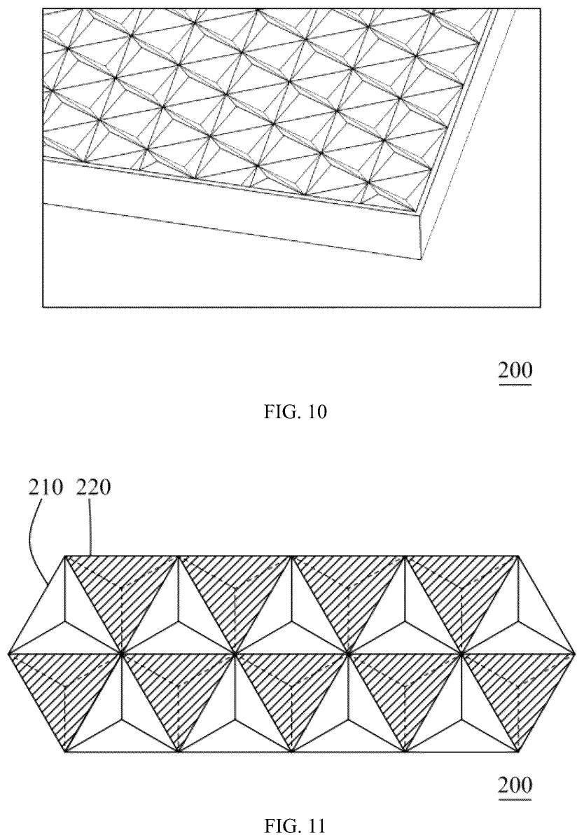

Please refer to FIGS. 7 to 9, FIG. 7 illustrates a schematic diagram of an optical film according to a first embodiment of the present invention, FIG. 8 illustrates a side cross-sectional view of the optical film, and FIG. 9 illustrates a schematic diagram of a microstructure. The optical film 100 of the present invention includes a first surface 1111 and a second surface 1112, the direction facing of the first surface 1111 is opposite to the direction facing of the second surface 1112. The first surface 1111 is disposed with a plurality of first microstructures 110 and second microstructures 120, the first microstructures 110 and the second microstructures 120 are closely adjacent to each other, wherein the first microstructures 110 are upwardly convex quadrangular pyramid structures, and the second microstructures 120 are downwardly concave quadrangular pyramid structures.

In particular, please refer to FIG. 9, which is a top view of the optical film 100, the first microstructure 110 and the second microstructure 120 are closely adjacent to each other, and in FIG. 9, the downwardly concave second microstructure 120 is represented by sectional lines. That is to say, the first surface 1111 of the optical film 100 has upwardly convex and downwardly concave microstructures arranged alternately.

Furthermore, please refer to FIG. 8, the upward convexity and downward concavity of the first microstructure 110 and the second microstructure 120 are defined by a reference plane 111 of the optical film 100. The reference plane 111 refers to the plane at the average height of the first microstructure 110 and the second microstructure 120. In other words, the apex of the upwardly convex first microstructure 110 is above the reference plane 111, the apex of the downwardly concave second microstructure 120 is below the reference plane, and the height of the first microstructure 110 is substantially equal to the depth of the second microstructure 120. In addition, the reference plane 111 is also the plane where the base of the quadrangular pyramid structure is located, and the first microstructure 110 and the second microstructure 120 are upwardly convex and downwardly concave microstructures formed by the quadrangular pyramid.

Please refer to FIGS. 10 and 11, which illustrate an optical film 200 of a second embodiment. In the embodiment of FIG. 10, the first microstructure 210 on the optical film 200 is formed by an upwardly convex triangular pyramid, and the second microstructure 220 is formed by a downwardly concave triangular pyramid. Further referring to FIG. 11, the first microstructure 210 and the second microstructure 220 are closely adjacent to each other, that is, the optical film 200 has upwardly convex and downwardly concave triangular pyramid microstructures arranged alternately.

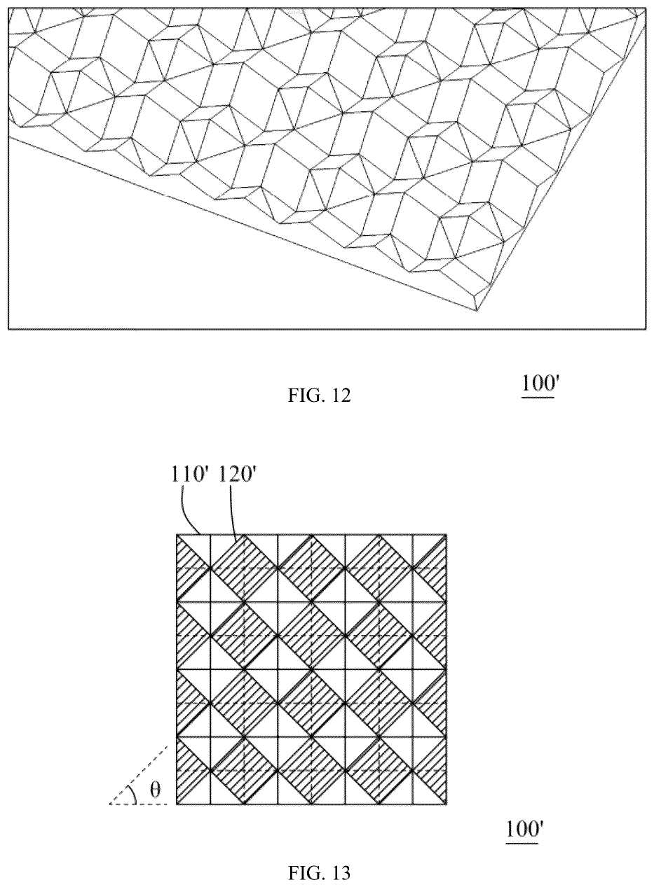

Next, please refer to FIGS. 12 and 13, which illustrate an optical film sheet 100′ of a third embodiment. In the embodiments of FIGS. 12 and 13, the arrangement direction of the first microstructure 110′ and the second microstructure 120′ is at an angle θ with the side of the optical film 100′, such as 45°. Furthermore, this angle θ is related to the arrangement of the light source 12 on the substrate 11.

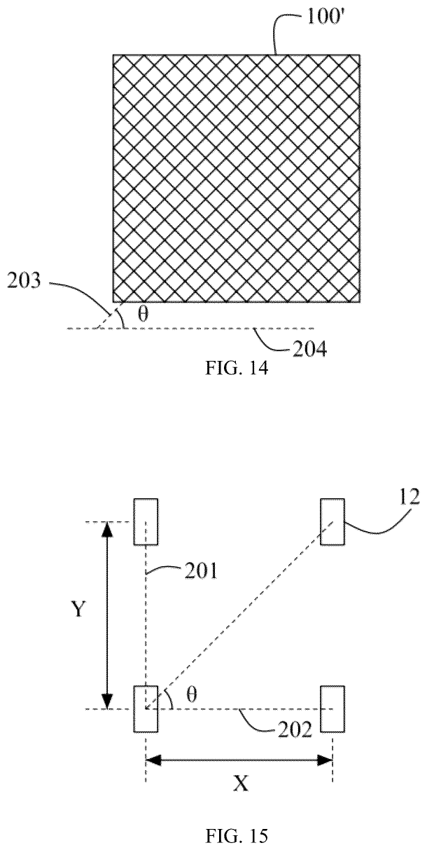

Please refer to FIGS. 14 and 15, which illustrate schematic diagrams of angle θ. The extension line 203 of the arrangement direction of the first microstructure 110′ and the second microstructure 120′ forms an angle θ with the horizontal line 204 of the edge of the optical film 100′. Next, refer to FIG. 15, the angle θ is determined by the arrangement of the light source 12, that is the angle between one light source 12 and the oblique light source 12. That is to say, the tangent function of the angle θ is equal to the distance Y of the light source 12 in the second direction 201 divided by the distance X of the light source 12 in the first direction 202, i.e., tan θ=Y/X. Therefore, the skew angle θ of the first microstructure 110′ and the second microstructure 120′ corresponds to the arrangement of the light source 12.

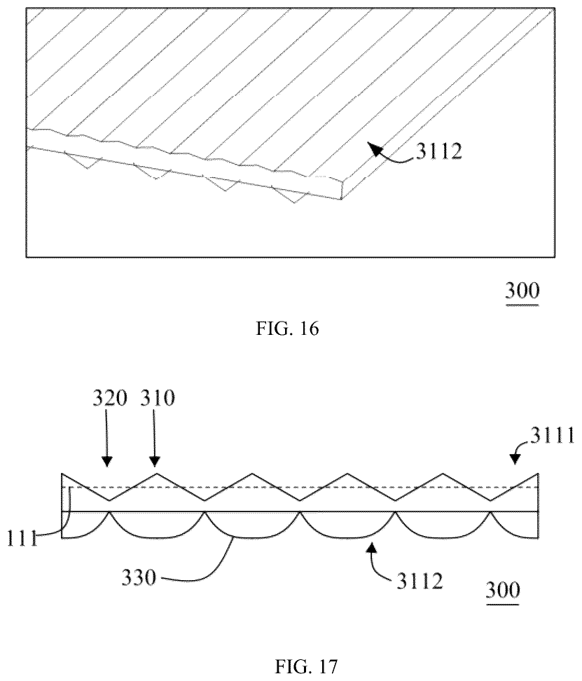

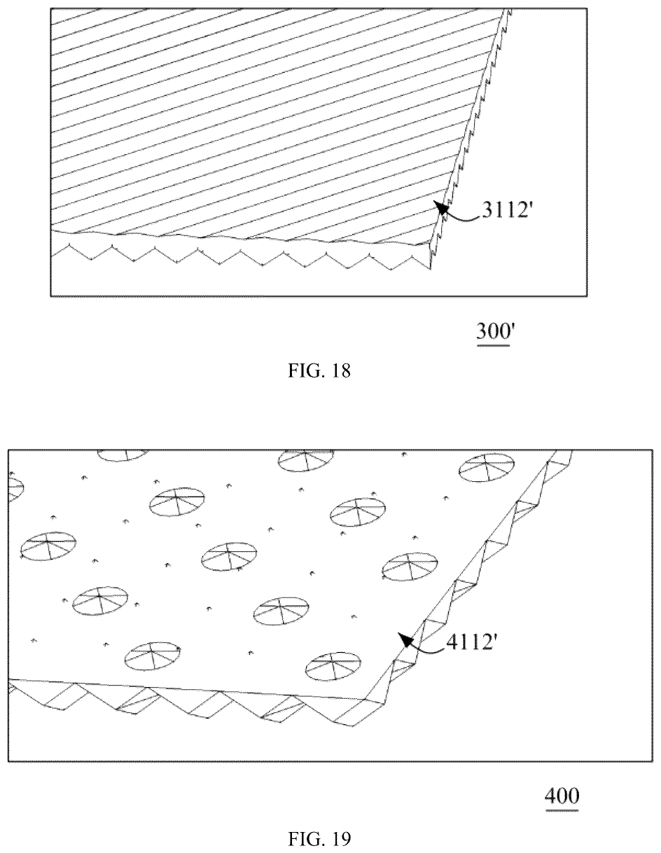

Please refer to FIGS. 16 and 17, which illustrate the second surface 3112 of the optical film 300 of the fourth embodiment. The first surface 3111 of the optical film 300 of this embodiment is similar to the previous embodiments, having microstructures with alternating upward convexity and downward concavity of the first microstructure 310 and the second microstructure 320, which will not be described again here. The feature of this embodiment is that the second surface 3112 of the optical film 300 also includes a plurality of third microstructures 330, which, for example, are cylindrical and arranged parallel to the second surface 3112 of the optical film 300. Please refer to FIG. 18, which illustrates the optical film 300′ of the fifth embodiment. In this embodiment, the plurality of third microstructures 330′ on the second surface 3112′ are similar to the third embodiment, and the extending direction of the third microstructures 330′ can form an angle θ with the edge of the optical film 300′.

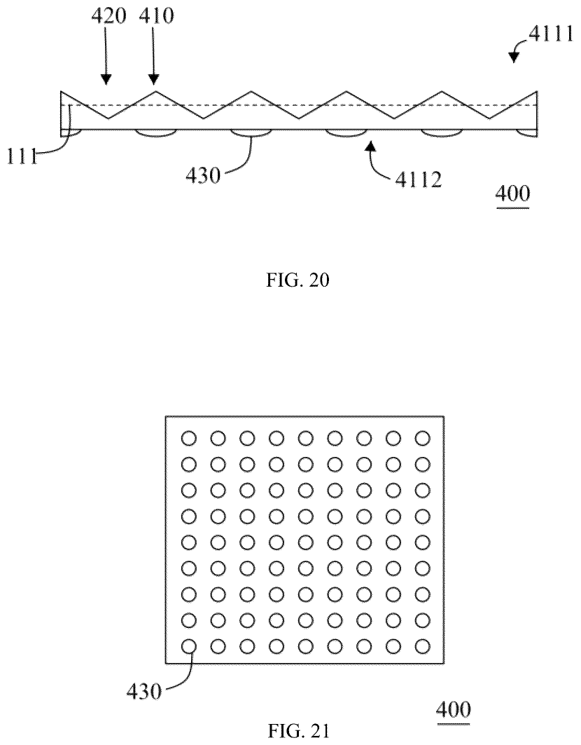

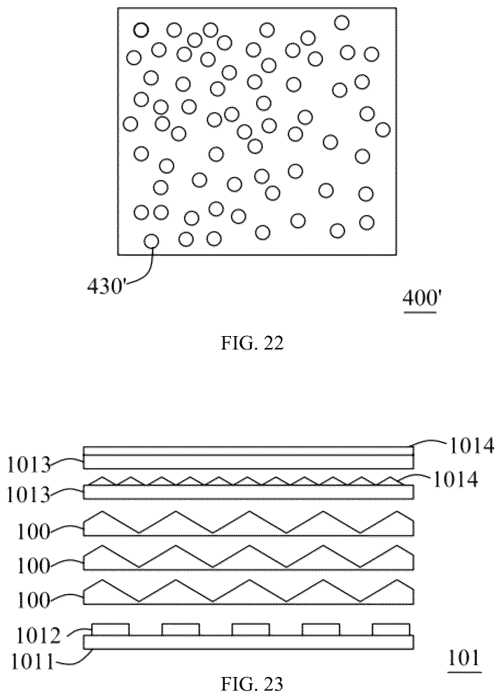

Please refer to FIGS. 19 and 20, which illustrate the optical film 400 of the sixth embodiment. The first surface 4111 of the optical film 400 of this embodiment is similar to the previous embodiments, having microstructures with alternating upward convexity and downward concavity of the first microstructure 410 and the second microstructure 420, which will not be described again here. The feature of this embodiment is that the second surface 4112 also includes a plurality of third microstructures 430, and the third microstructures 430 present a circular convex lens shape and are dispersedly arranged on the second surface 4112. Next, please refer to FIGS. 21 and 22, which illustrate the arrangement of the third microstructures 430. As shown in FIG. 21, the circular convex lens-shaped third microstructures 430 can be neatly arranged on the second surface 4112. In another embodiment, as shown in FIG. 22, the circular convex lens-shaped third microstructures 430 can also be randomly arranged on the second surface 4112.

Please refer to FIG. 23, which shows a schematic diagram of a backlight module. The backlight module 101 is an application of the optical film of the present invention, and the backlight module 101 of this embodiment includes a light source array 1011, a plurality of optical films 100, and a plurality of prism sheets 1013. The light source array 1011 includes a plurality of light sources 1012, such as light-emitting diodes (LEDs) or mini light-emitting diodes (Mini LEDs). The a plurality of optical films 100 are arranged above the light source array 1011, with the second surface facing the light sources 1012 to receive light from the light sources 1012. Moreover, the a plurality of optical films 100 are stacked on top of each other. These optical films 100 are, for example, the optical films 100, 100′, 200, 300, 300′, or 400 of the aforementioned embodiments, and can be stacked using the same type of optical film or a combination thereof.

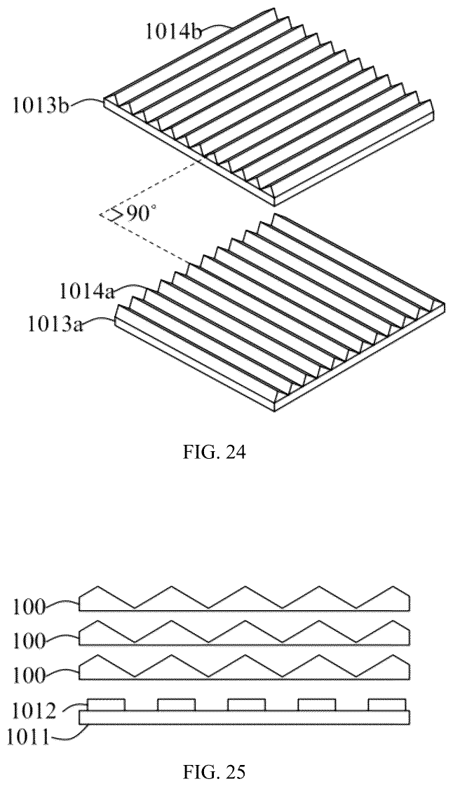

The prism sheets 1013 are stacked on top of the optical films 100. Please refer to FIG. 24, which shows a schematic diagram of the arrangement of the prism sheets. Each prism sheet 1013 has a plurality of triangular prism structures 1014 on its top surface, with the extending direction of the triangular prism structures 1014a of one prism sheet 1013a perpendicular to the extending direction of the triangular prism structures 1014b of another prism sheet 1013b. In detail, when a plurality of prism sheets 1013a, 1014a are stacked vertically, the triangular prism structures 1014a of each prism sheet 1013a and the triangular prism structures 1014b of the adjacent prism sheet 1013b form an angle of 90 degrees in the horizontal extending direction.

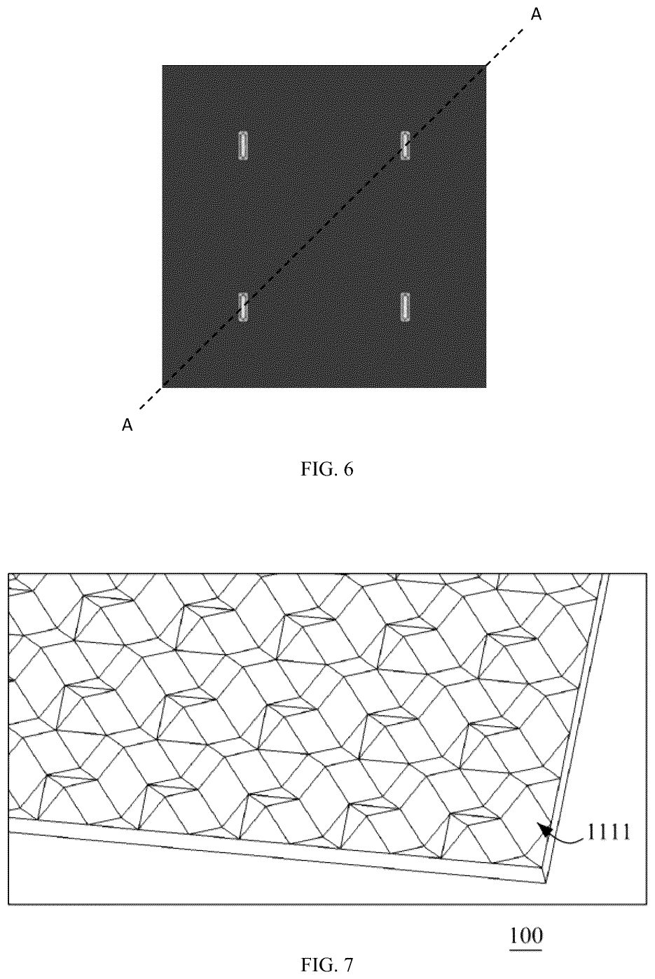

Different combinations of optical films and prism sheets arranged above the light sources can produce different diffusion effects. The following will describe the different combinations and simulated brightness distribution diagrams. As shown in FIG. 6, the brightness distribution diagrams shown below are generated by the cross-section line of the optical simulation diagram A-A, with the light sources 12 positioned between the horizontal axis 5, 4 and −4, −5.

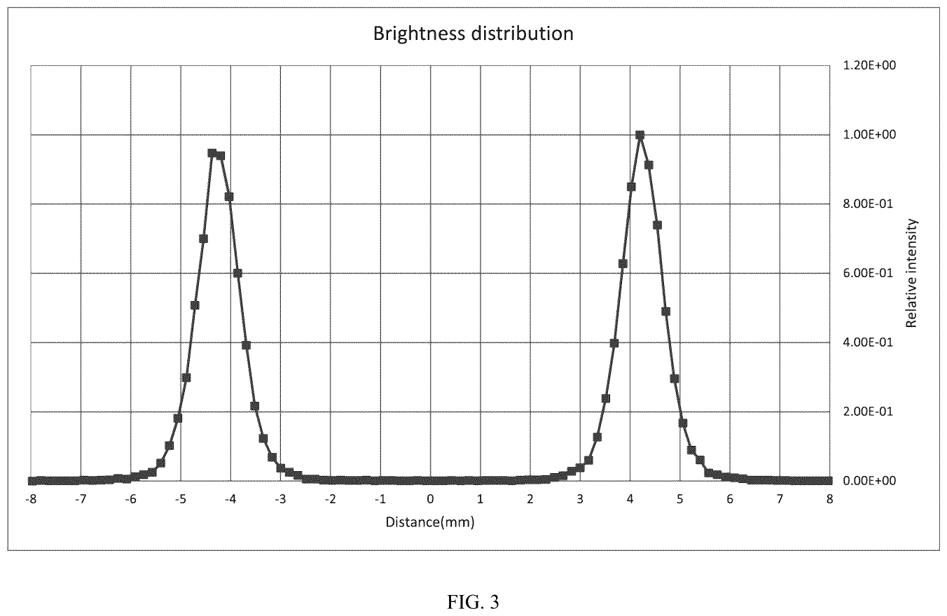

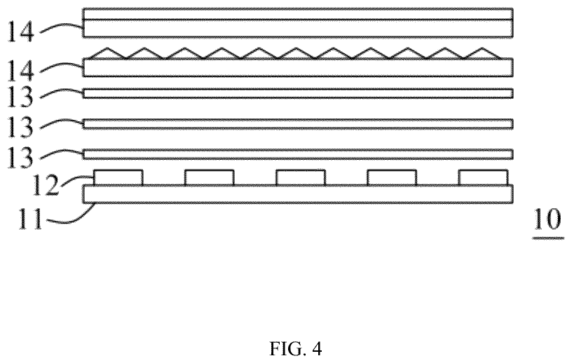

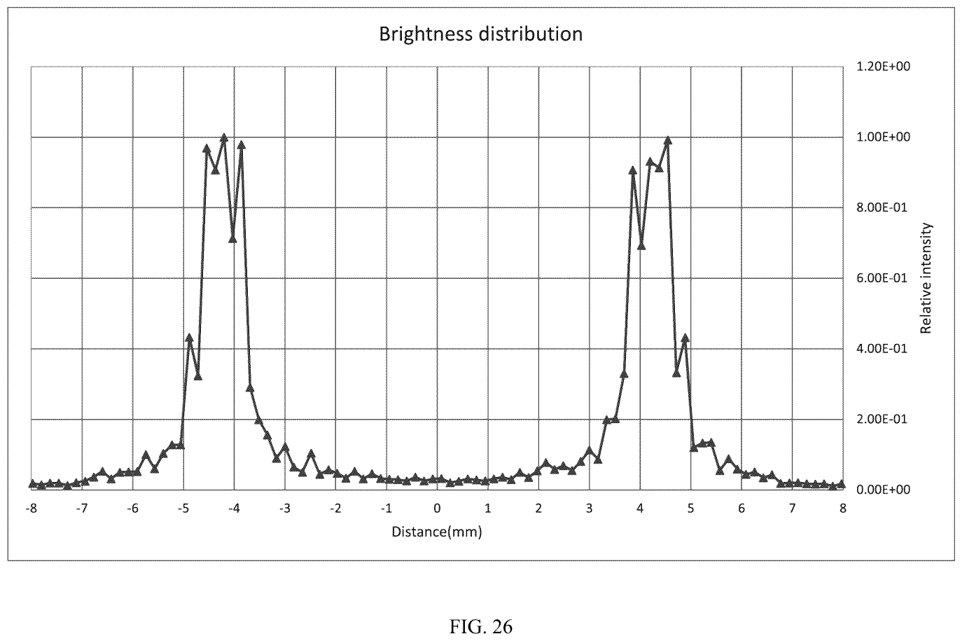

Please refer to FIGS. 25 and 26, with FIG. 25 showing the first embodiment of the backlight module and FIG. 26 showing the brightness distribution diagram of the first embodiment of the backlight module. This embodiment of the backlight module includes three optical films 100 from the aforementioned embodiments (as shown in FIGS. 7 to 9). Compared to the brightness distribution diagram in FIG. 3, it can be seen from FIG. 26 that the overall brightness is reduced and the diffusion effect is better than that in FIG. 3.

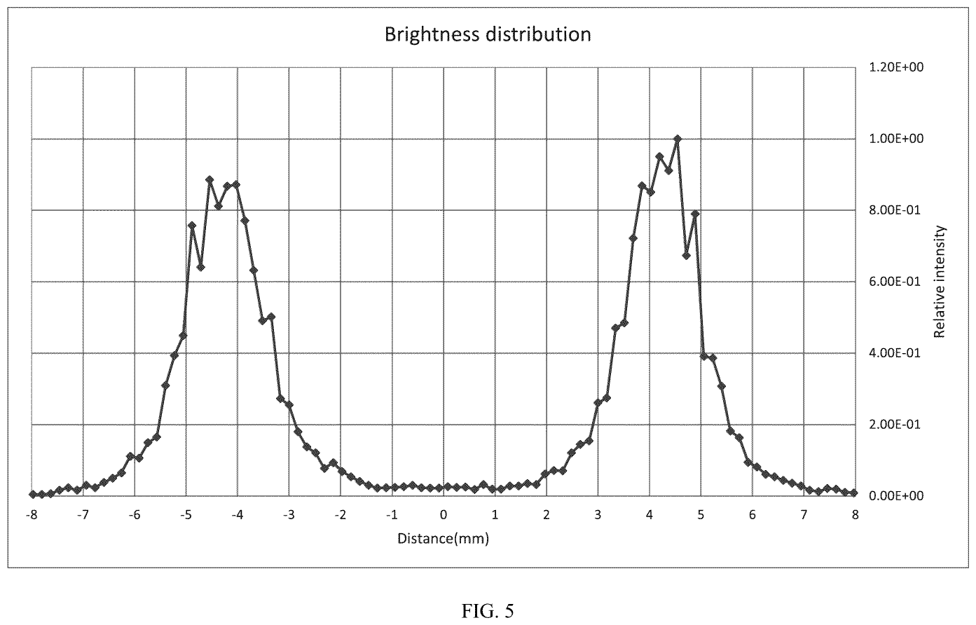

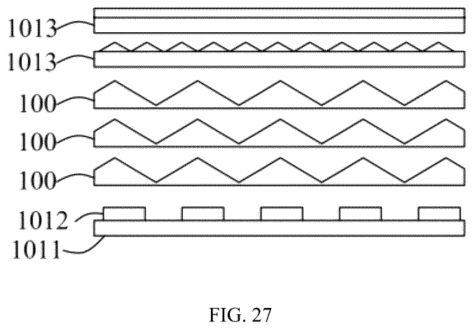

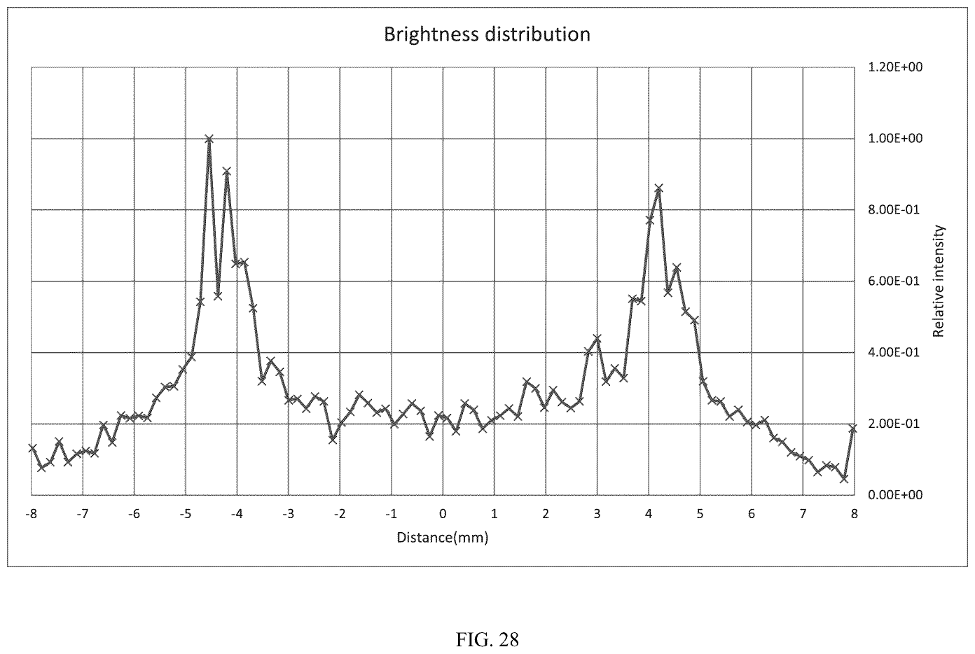

Please refer to FIGS. 27 and 28, with FIG. 27 showing the second embodiment of the backlight module and FIG. 28 showing the brightness distribution diagram of the second embodiment of the backlight module. This embodiment of the backlight module includes three optical films 100 of the aforementioned first embodiment (as shown in FIGS. 7 to 9), and also includes two prism sheets 1013 above the optical films 100, with the two prism sheets 1013 stacked in a vertically staggered manner (as shown in FIG. 24). Compared to the brightness distribution diagram in FIG. 5, it can be seen from FIG. 28 that the brightness at the light source is further reduced, the light range is significantly wider, and the diffusion effect is better than that in FIG. 5.

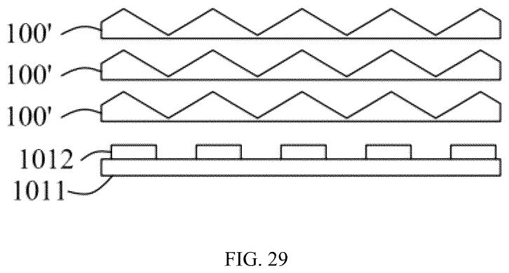

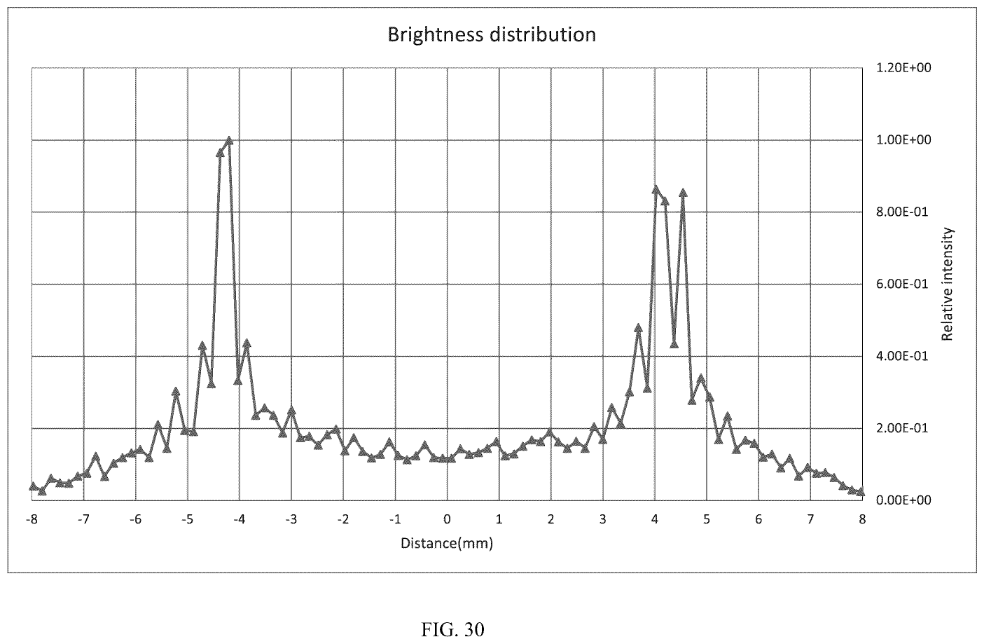

Please refer to FIGS. 29 and 30, with FIG. 29 showing the third embodiment of the backlight module and FIG. 30 showing the brightness distribution diagram of the third embodiment of the backlight module. This embodiment of the backlight module includes three optical films 100′ from the aforementioned embodiments (as shown in FIGS. 12 to 3C), that is, the microstructures on the optical film and the edge of the optical film have an angle θ. Compared to the brightness distribution diagram in FIG. 3, it can be seen from FIG. 30 that the brightness at the light source is further reduced, the light range is significantly wider, and the diffusion effect is better than that in FIG. 3. Furthermore, when compared to FIG. 26, it can be seen from FIG. 30 that by tilting the microstructures, a better light diffusion effect can be achieved.

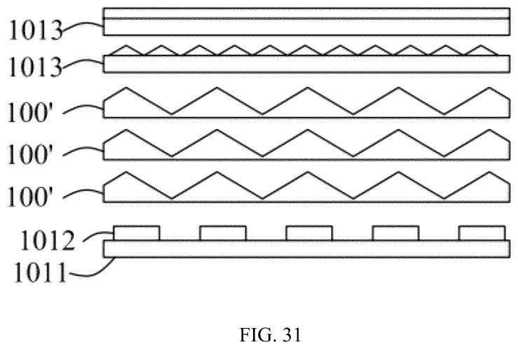

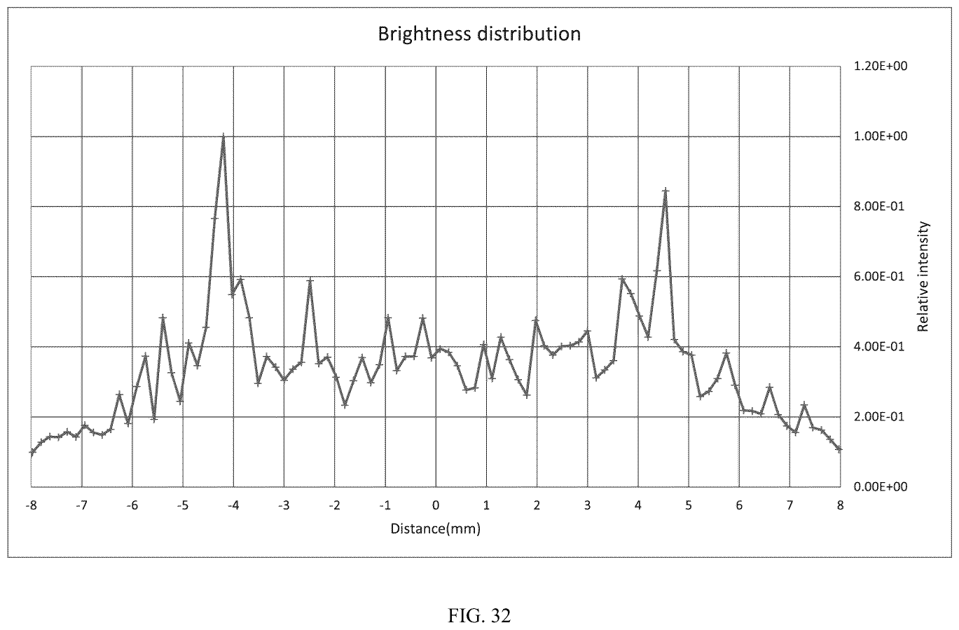

Please refer to FIGS. 31 and 32, with FIG. 31 showing the fourth embodiment of the backlight module and FIG. 32 showing the brightness distribution diagram of the fourth embodiment of the backlight module. This embodiment of the backlight module includes three optical films 100′ from the aforementioned embodiments (as shown in FIG. 12), and also includes two prism sheets 1013 above the optical films 100′, with the two prism sheets 1013 stacked in a vertically staggered manner (as shown in FIG. 24). Compared to the brightness distribution diagram in FIG. 5, it can be seen from FIG. 32 that the bright area at the light source almost disappears, the light range is significantly wider, and the diffusion effect is better than that in FIG. 5.

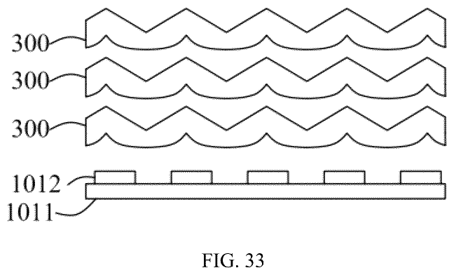

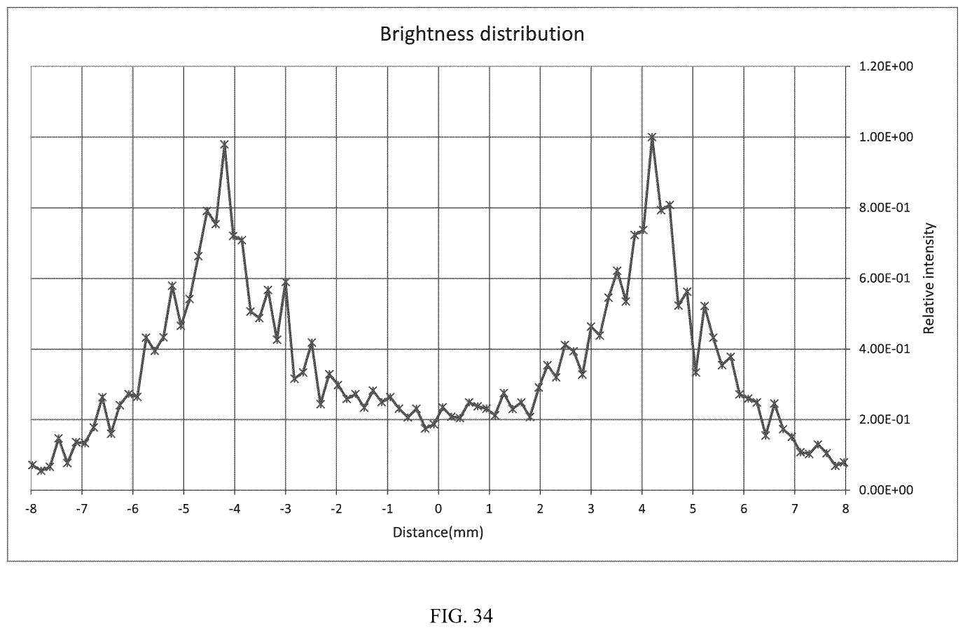

Please refer to FIGS. 33 and 34, with FIG. 33 showing the fifth embodiment of the backlight module and FIG. 34 showing the brightness distribution diagram of the fifth embodiment of the backlight module. This embodiment of the backlight module includes three optical films 300 from the aforementioned embodiments (as shown in FIGS. 16 and 17), that is, the third microstructures with a cylindrical shape are located on the second surface. Compared to the brightness distribution diagram in FIG. 3, it can be seen from FIG. 34 that the brightness at the light source is significantly reduced, the light range is significantly wider, and the diffusion effect is better than that in FIG. 3.

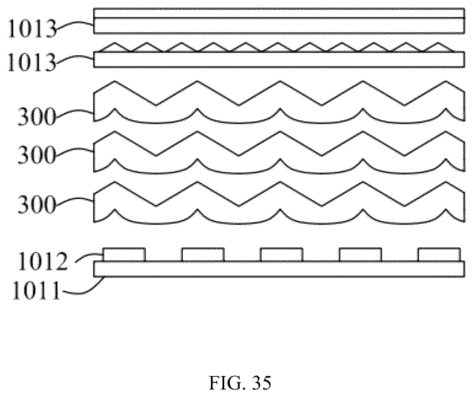

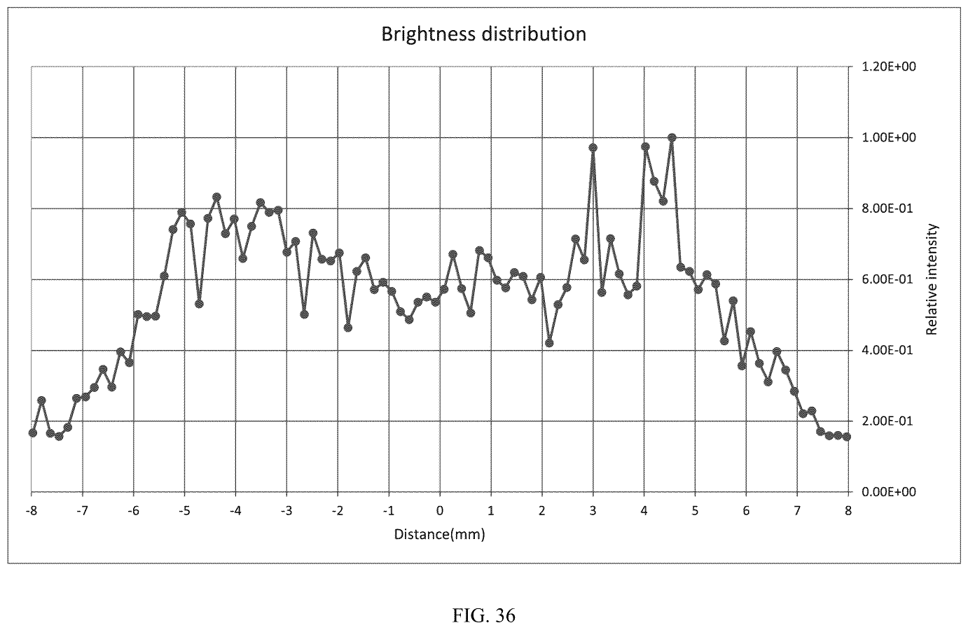

Please refer to FIGS. 35 and 36, with FIG. 35 showing the sixth embodiment of the backlight module and FIG. 36 showing the brightness distribution diagram of the sixth embodiment of the backlight module. This embodiment of the backlight module includes three optical films 300 from the aforementioned embodiments (as shown in FIGS. 16 and 17), and also includes two prism sheets 1013 above the optical films 100′, with the two prism sheets 1013 stacked in a vertically staggered manner (as shown in FIG. 24). Compared to the brightness distribution diagram in FIG. 5, it can be seen from FIG. 36 that the highlight area at the light source almost disappears, the light range is significantly wider, and the diffusion effect is better than that in FIG. 5.

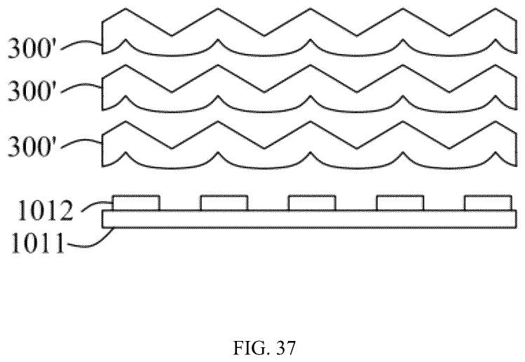

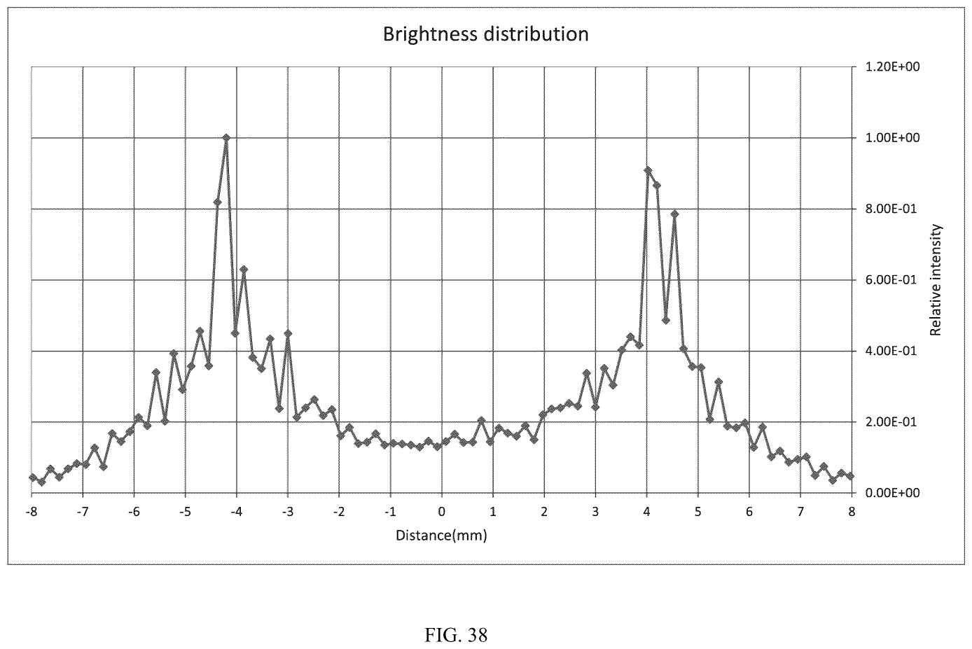

Please refer to FIGS. 37 and 38, with FIG. 37 showing the seventh embodiment of the backlight module and FIG. 38 showing the brightness distribution diagram of the seventh embodiment of the backlight module. This embodiment of the backlight module includes three optical films 300′ from the aforementioned embodiments (as shown in FIG. 18), that is, the third microstructures have an angle with the edge of the optical film. Compared to the brightness distribution diagram in FIG. 3, it can be seen from FIG. 38 that the brightness at the light source is significantly reduced, the light range is significantly wider, and the diffusion effect is better than that in FIG. 3.

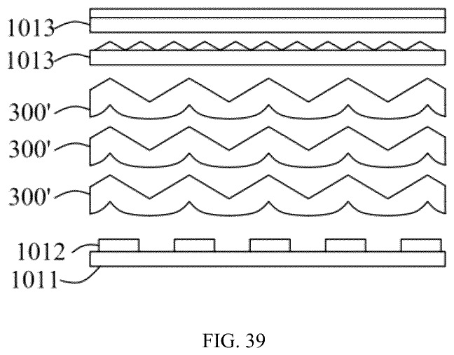

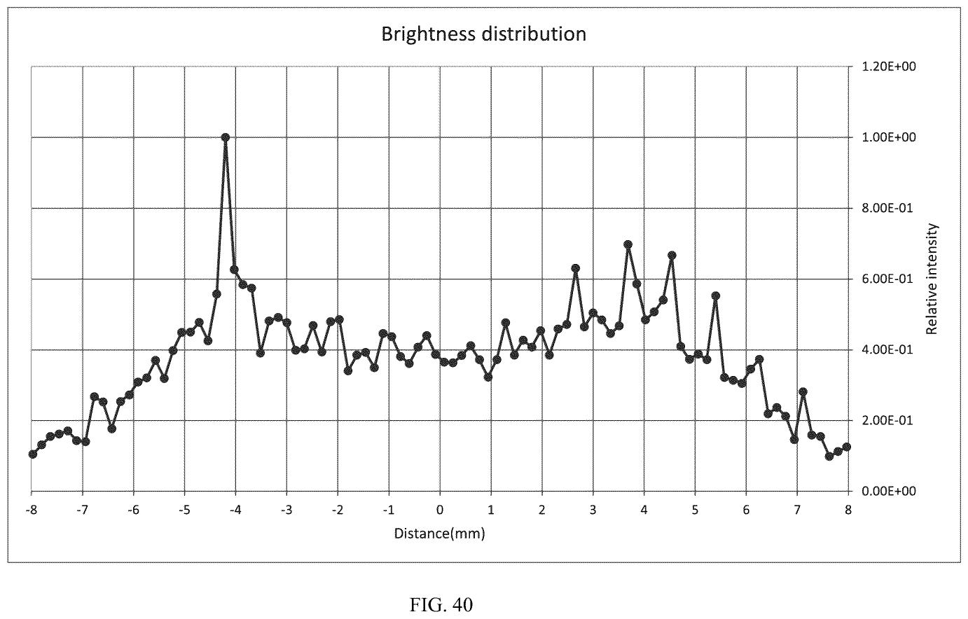

Please refer to FIGS. 39 and 40, with FIG. 39 showing the eighth embodiment of the backlight module and FIG. 40 showing the brightness distribution diagram of the eighth embodiment of the backlight module. This embodiment of the backlight module includes three optical films 300′ from the aforementioned embodiments (as shown in FIG. 18), and also includes two prism sheets 1013 above the optical films 300′, with the two prism sheets 1013 stacked in a vertically staggered manner (as shown in FIG. 24). Compared to the brightness distribution diagram in FIG. 5, it can be seen from FIG. 40 that the highlight area at the light source almost disappears, the light range is significantly wider, and the diffusion effect is better than that in FIG. 5.

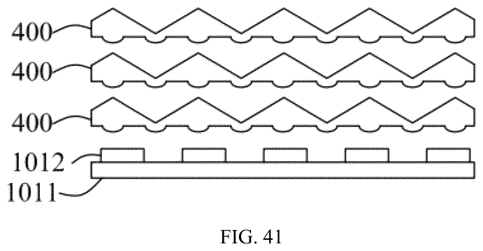

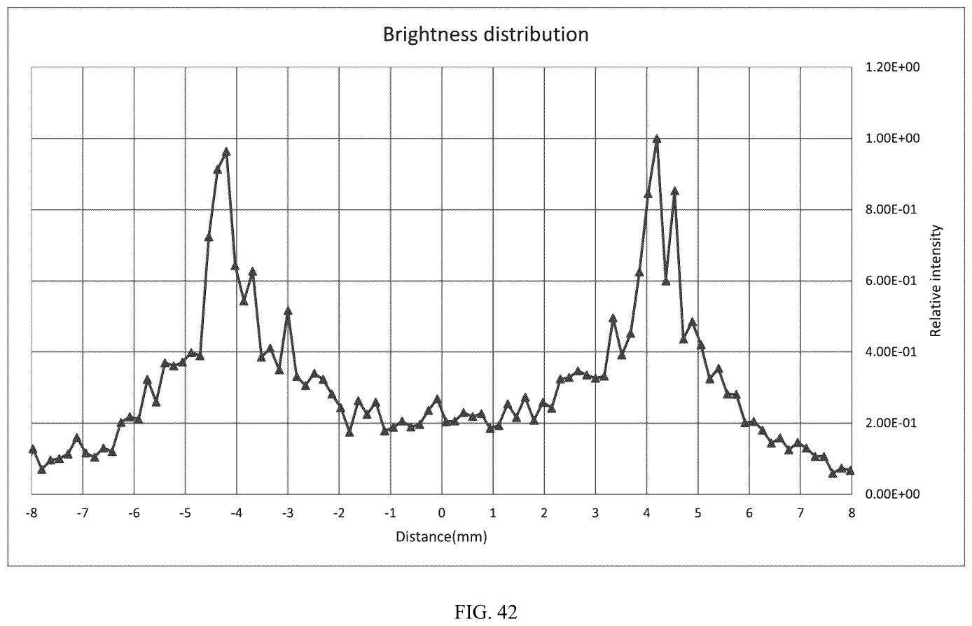

Please refer to FIGS. 41 and 42, with FIG. 41 showing the ninth embodiment of the backlight module and FIG. 42 showing the brightness distribution diagram of the ninth embodiment of the backlight module. This embodiment of the backlight module includes three optical films 400 from the aforementioned embodiments (as shown in FIGS. 19 to 22), that is, the third microstructures have a circular lens shape on the second surface. Compared to the brightness distribution diagram in FIG. 3, it can be seen from FIG. 42 that the brightness at the light source is significantly reduced, the light range is significantly wider, and the diffusion effect is better than that in FIG. 3.

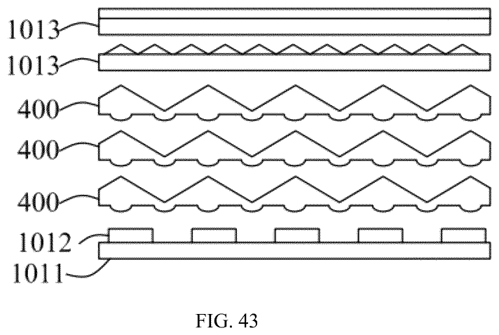

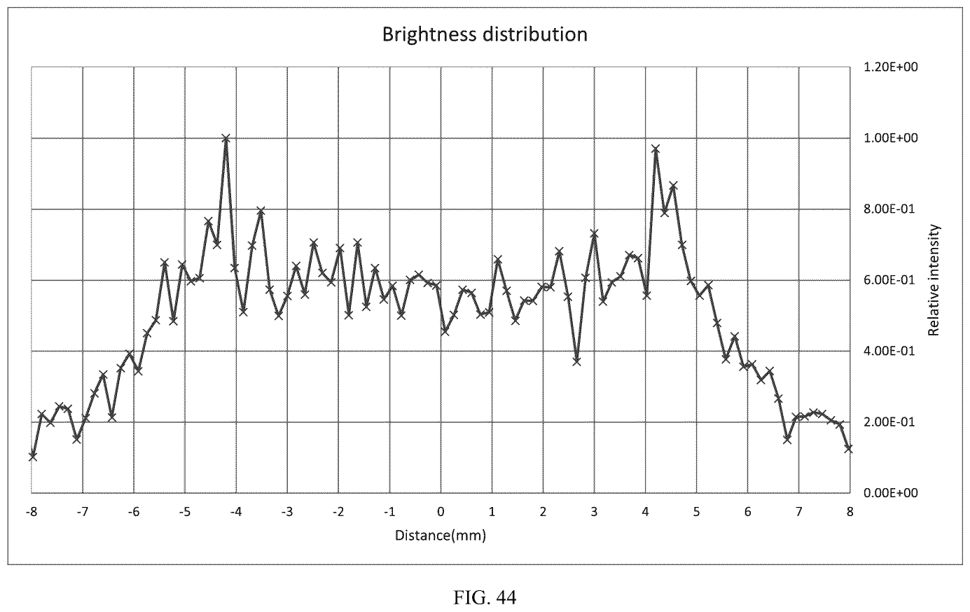

Please refer to FIGS. 43 and 44, with FIG. 43 showing the tenth embodiment of the backlight module and FIG. 44 showing the brightness distribution diagram of the tenth embodiment of the backlight module. This embodiment of the backlight module includes three optical films 400 from the aforementioned embodiments (as shown in FIGS. 19 to 22), and also includes two prism sheets 1013 above the optical films 400, with the two prism sheets 1013 stacked in a vertically staggered manner (as shown in FIG. 24). Compared to the brightness distribution diagram in FIG. 5, it can be seen from FIG. 44 that the highlight area at the light source almost disappears, the light range is significantly wider, and the diffusion effect is better than that in FIG. 5.

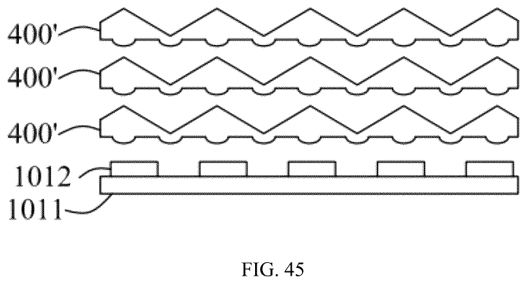

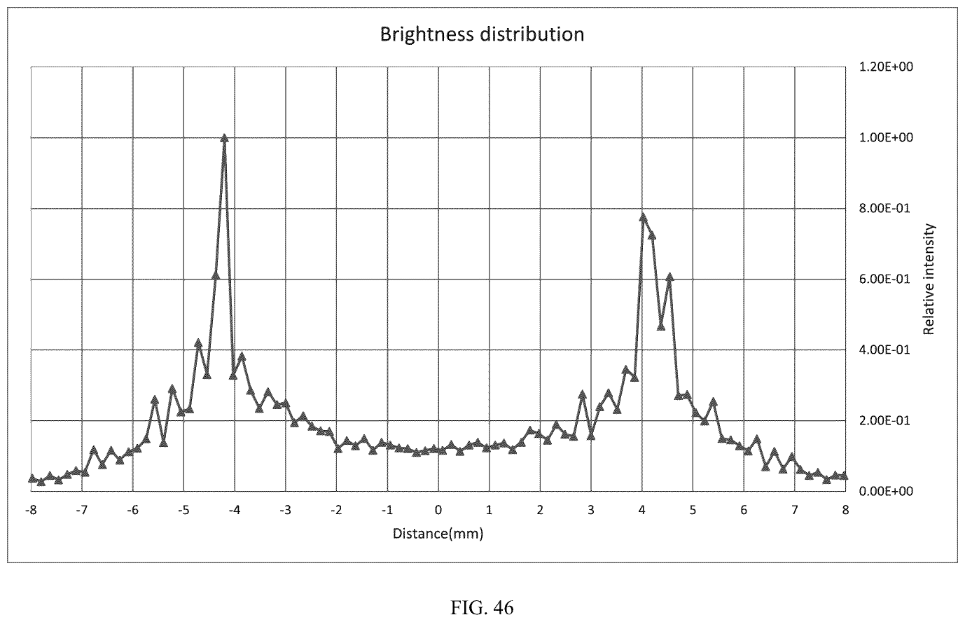

Please refer to FIGS. 45 and 46, with FIG. 45 showing the eleventh embodiment of the backlight module and FIG. 46 showing the brightness distribution diagram of the eleventh embodiment of the backlight module. This embodiment of the backlight module includes three optical films 400′ from the aforementioned embodiments, with the microstructures on the optical film having an angle with the edge of the optical film. Compared to the brightness distribution diagram in FIG. 3, it can be seen from FIG. 46 that the brightness at the light source is reduced, the light range is significantly wider, and the diffusion effect is better than that in FIG. 3.

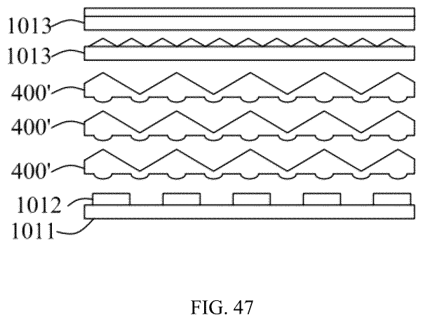

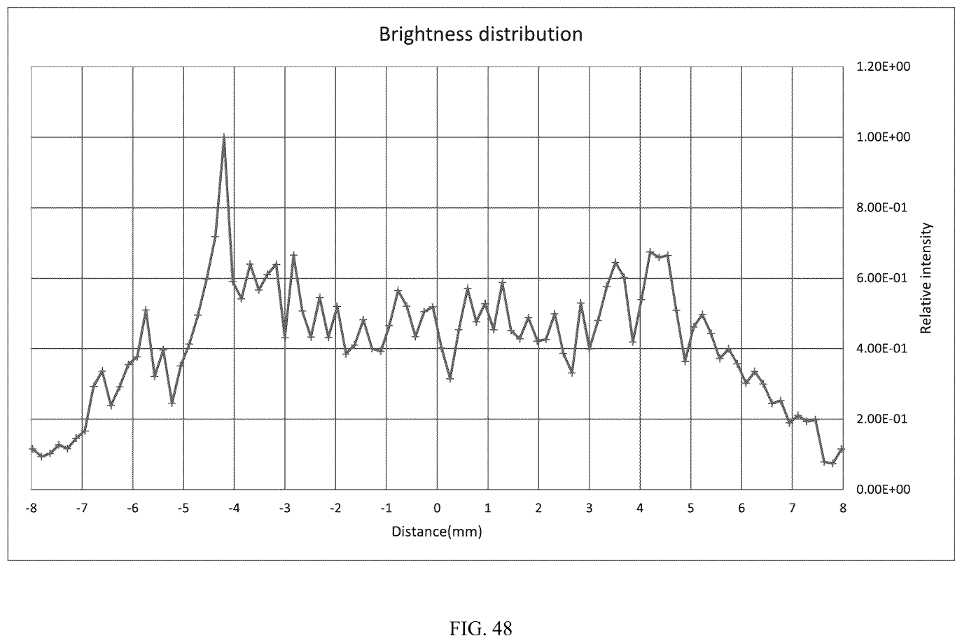

Please refer to FIGS. 47 and 48, with FIG. 47 showing the twelfth embodiment of the backlight module and FIG. 48 showing the brightness distribution diagram of the twelfth embodiment of the backlight module. This embodiment of the backlight module includes three optical films 400′ from the aforementioned embodiments, and also includes two prism sheets 1013 above the optical films 400′, with the two prism sheets 1013 stacked in a vertically staggered manner (as shown in FIG. 24). Compared to the brightness distribution diagram in FIG. 3, it can be seen from FIG. 48 that the highlight area at the light source almost disappears, the light range is significantly wider, and the diffusion effect is better than that in FIG. 5.

The optical film of the present invention, having upwardly convex and downwardly concave microstructures, can effectively improve the light diffusion effect of the light source, enabling the light to cover the display area better. Compared to the conventional backlight module technology, the backlight module of the present invention can provide a better light performance. At the same time, it can reduce the density of the light-emitting components while achieving a comparable light performance, allowing for the use of fewer LEDs in the backlight module, which further reduces the manufacturing cost of the backlight module. In addition, the upwardly convex and downwardly concave microstructures reduce the contact area between the optical films, further reducing the static electricity generated by the optical films in the backlight module.

Although the invention has been disclosed and illustrated with reference to particular embodiments, the principles involved are susceptible for use in numerous other embodiments that will be apparent to persons skilled in the art. This invention is, therefore, to be limited only as indicated by the scope of the appended claims.

What is claimed is:

1. An optical film comprising a first surface and a second surface, wherein the first surface and the second surface face in opposite directions, the first surface disposed with a plurality of first microstructures and a plurality of second microstructures, and the first microstructures and the second microstructures are closely adjacent to each other; wherein the first microstructures are upwardly convex quadrangular pyramid structures, and the second microstructures are downwardly concave quadrangular pyramid structures.

2. The optical film according to claim 1, wherein a plurality of third microstructures are disposed on the second surface.

3. The optical film according to claim 2, wherein the third microstructures are cylindrical.

4. The optical film according to claim 2, wherein the third microstructures are circular convex lens-shaped.

5. The optical film according to claim 4, wherein the third microstructures are arranged in a random pattern.

6. The optical film according to claim 1, wherein the arrangement direction of the first microstructures and the second microstructures is at a 45-degree angle with respect to a side edge of the optical film.

7. An optical film comprising a first surface and a second surface, wherein the first surface and the second surface face in opposite directions, and the first surface is disposed with a plurality of first microstructures and a plurality of second microstructures, and the first microstructures and the second microstructures are closely adjacent to each other; wherein the first microstructures are upwardly convex triangular pyramid structures, and the second microstructures are downwardly concave triangular pyramid structures.

8. The optical film according to claim 7, wherein a plurality of third microstructures are disposed on the second surface.

9. The optical film according to claim 8, wherein the third microstructures are cylindrical.

10. The optical film according to claim 8, wherein the third microstructures are circular convex lens-shaped.

11. The optical film according to claim 10, wherein the third microstructures are arranged in a random pattern.

12. The optical film according to claim 7, wherein the arrangement direction of the first microstructures and the second microstructures is at a 45-degree angle with respect to the side edge of the optical film.

13. A backlight module, comprising:
a light source array, comprising a plurality of light sources; and
a plurality of optical films, arranged above the light source array and stacked on top of each other;
wherein the optical films comprise a first surface and a second surface, the first surface and the second surface face in opposite directions, and the first surface is disposed with a plurality of first microstructures and a plurality of second microstructures, and the first microstructures and the second microstructures are closely adjacent to each other
wherein the first microstructures are upwardly convex quadrangular pyramid structures or triangular pyramid structures, and the second microstructures are downwardly concave quadrangular pyramid structures or triangular pyramid structures.

14. The backlight module according to claim 13, wherein a plurality of third microstructures are disposed on the second surface.

15. The backlight module according to claim 14, wherein the third microstructures are cylindrical.

16. The backlight module according to claim 14, wherein the third microstructures are circular convex lens-shaped.

17. The backlight module according to claim 16, wherein the third microstructures are arranged in a random pattern.

18. The backlight module according to claim 13, wherein the arrangement direction of the first microstructures and the second microstructures is at a 45-degree angle with respect to the side edge of the optical film.

19. The backlight module according to claim 13, further comprising at least one prism sheet, the prism sheet being arranged above the optical films, and the top surface of the prism sheet is disposed with a plurality of triangular prism structures.
